(19) United States
(12) Patent Application Publication
(10) Pub. No.: US 2020/0243768 A1
(43) Pub. Date: Jul. 30, 2020

(54) METHODS OF OPERATING A VACUUM PROCESSING SYSTEM

(71) Applicant: Applied Materials, Inc., Santa Clara, CA (US)

(72) Inventors: Sebastian Gunther ZANG, Mainaschaff (DE); Andreas SAUER, Großostheim (DE)

(21) Appl. No.: 15/760,661

(22) PCT Filed: Mar. 17, 2017
(86) PCT No.: PCT/EP2017/056385

§ 371 Date: Mar. 16, 2018

(51) Int. Cl. H01L 51/00; C23C 14/04; C23C 14/56; C23C 16/04; C23C 16/54; H01L 21/67; H01L 21/677

(52) U.S. Cl. CPC H01L 51/001; C23C 14/042; C23C 14/568; C23C 16/042; H01L 21/6776; H01L 21/67184; H01L 21/67712; H01L 21/67715; C23C 16/54

(57) ABSTRACT

A method of operating a vacuum processing system with a main transportation path along which substrates can be transported in a main transportation direction is described. The method includes routing a substrate out of the main transportation path into a first deposition module for depositing a first material on the substrate; routing the substrate out of the main transportation path into a second deposition module for depositing a second material on the substrate; and routing the substrate out of the main transportation path into one or more further deposition modules for depositing one or more further materials on the substrate. Further, various methods of operating one or more rotation modules of vacuum processing system configured for depositing two or more materials on a plurality of substrates are described.

### TECHNICAL FIELD

Embodiments of the present disclosure relate to methods of operating a vacuum processing system, particularly for depositing two, three or more different materials on a plurality of substrates. Embodiments particularly relate to methods of operating a vacuum processing system, wherein substrates which are held by substrate carriers are transported in the vacuum processing system along a substrate transportation path, e.g. into various deposition modules and out of various deposition modules.

### BACKGROUND

Opto-electronic devices that make use of organic materials are becoming increasingly popular for a number of reasons. Many of the materials used to make such devices are relatively inexpensive, so organic opto-electronic devices have the potential for cost advantages over inorganic devices. The inherent properties of organic materials, such as their flexibility, may be advantageous for applications such as for the deposition on flexible or inflexible substrates. Examples of organic opto-electronic devices include organic light emitting devices, organic phototransistors, organic photovoltaic cells, and organic photodetectors.

The organic materials of OLED devices may have performance advantages over conventional materials. For example, the wavelength at which an organic emissive layer emits light may be readily tuned with appropriate dopants. OLED devices make use of thin organic films that emit light when a voltage is applied across the device. OLED devices are becoming an increasingly interesting technology for use in applications such as flat panel displays, illumination, and backlighting.

Materials, particularly organic materials, are typically deposited on a substrate in a vacuum processing system under sub-atmospheric pressure. During deposition, a mask device may be arranged in front of the substrate, wherein the mask device may have at least one opening or a plurality of openings that define an opening pattern corresponding to a material pattern to be deposited on the substrate, e.g. by evaporation. The substrate is typically arranged behind the mask device during the deposition and is aligned relative to the mask device. For example, a mask carrier may be used to transport the mask device into a deposition chamber of the vacuum processing system, and a substrate carrier may be used to transport the substrate into the deposition chamber for arranging the substrate behind the mask device.

Typically, two, three, five, ten or more materials may subsequently be deposited on a substrate, e.g. for manufacturing a color display. It may be difficult to handle a vacuum processing system comprising a plurality of deposition modules for depositing different materials on a plurality of substrates. In particular, handling the substrate traffic and the mask traffic in large vacuum processing systems for depositing different materials may be challenging.

Accordingly, it would be beneficial to provide methods of reliably operating a vacuum processing system for the deposition of materials on a plurality of substrates. In particular, simplifying and accelerating the substrate and mask transport and exchange in a vacuum processing system configured for masked deposition on substrates would be beneficial.

### SUMMARY

In light of the above, various methods of operating vacuum processing systems and vacuum processing systems for depositing different materials on a plurality of substrates are provided.

According to one aspect of the present disclosure, a method of operating a vacuum processing system with a main transportation path along which substrates can be transported is provided. The method includes routing a substrate out of the main transportation path into a first deposition module for depositing a first material on the substrate; routing the substrate out of the main transportation path into a second deposition module for depositing a second material on the substrate; and routing the substrate out of the main transportation path into one or more further deposition modules for depositing one or more further materials on the substrate.

According to an aspect of the present disclosure, a method of operating a vacuum processing system including a rotation module is provided. The method includes moving, during a time period, a first carrier carrying a substrate or a mask device on a first track in a first direction into the rotation module; and moving, during the time period, a second carrier on a second track in a second direction opposite to the first direction into or out of the rotation module.

According to an aspect of the present disclosure, a method of operating a vacuum processing system including a rotation module is provided. The method includes moving, during a time period, a first carrier carrying a first substrate on a first track in a first direction out of the rotation module; and moving, during the time period, a second carrier carrying a second substrate on the first track in the first direction into the rotation module.

According to an aspect of the present disclosure, a method of operating a vacuum processing including a rotation module system is provided. The method includes moving a first carrier carrying a first substrate or a first mask device on a first track into the rotation module, while a second carrier carrying a second substrate is arranged on a second track in the rotation module and/or while a third carrier carrying a second mask device is arranged on a third track in the rotation module.

According to an aspect of the present disclosure, a method of operating a vacuum processing system including a rotation module is provided. The method includes moving a first carrier carrying a substrate on a first track into the rotation module and moving a second carrier carrying a mask device on a second track adjacent to the first track into the rotation module; and simultaneously rotating the first carrier and the second carrier in the rotation module.

According to an aspect of the present disclosure, a method of operating a vacuum processing system including a rotation module and a deposition area is provided. The method includes moving, during a first time period, a coated substrate and a used mask device from the deposition area into the rotation module, followed by rotating the coated substrate and the used mask device in the rotation module during a second time period; and/or moving, during a third time period, a substrate to be coated and a mask device to be used from a main transportation path into the rotation module, followed by rotating the substrate to be coated and the mask device to be used in the rotation module during a fourth time period.

According to an aspect of the present disclosure, a vacuum processing system is provided. The vacuum processing system includes one or more transit modules and a first rotation module arranged along a main transportation path; a carrier transportation system configured for transporting carriers along the main transportation path; a first deposition module for depositing a first material which is arranged adjacent to the first rotation module on a first side of the main transportation path; and a second deposition module for depositing a second material which is arranged adjacent to the first rotation module on a second side of the main transportation path opposite the first deposition module.

According to an aspect of the present disclosure, a vacuum processing system is provided. The vacuum processing system includes one or more transit modules and a first rotation module arranged along a main transportation path; a carrier transportation system configured for transporting carriers along the main transportation path; a first deposition module for depositing a first material which is arranged adjacent to the first rotation module on a first side of the main transportation path; a second-line first deposition module for depositing the first material which is arranged adjacent to the first rotation module on a second side of the main transportation path opposite the first side; a second deposition module for depositing a second material which is arranged adjacent to the first rotation module on the second side of the main transportation path; and a second-line second deposition module for depositing the second material which is arranged adjacent to the first rotation module on the first side of the main transportation path.

According to an aspect of the present disclosure, a vacuum processing system is provided. The vacuum processing system includes one or more transit modules, a first rotation module and a second rotation module provided along a main transportation path; a carrier transportation system configured for transporting carriers along the main transportation path; a first deposition module for depositing the first material which is arranged adjacent to the first rotation module on a first side of the main transportation path; a second deposition module for depositing the second material which is arranged adjacent to the second rotation module on the first side of the main transportation path; a second-line first deposition module for depositing the first material which is arranged adjacent to the first rotation module on a second side of the main transportation path opposite the first deposition module; and a second-line second deposition module for depositing the second material which is arranged adjacent to the second rotation module on the second side of the main transportation path opposite the second deposition module.

Optionally, further rotation modules may be arranged along the main transportation path, and further deposition modules may be arranged next to the further rotation modules on the first side and/or on the second side of the main transportation path adjacent to a respective rotation module. The further deposition modules may be configured for depositing further materials on the substrate, e.g. a third material, a fourth material and/or further materials. A stack of materials, e.g. including ten or more different materials, can be deposited on a substrate in a vacuum processing system according to some embodiments described herein.

Further aspects, advantages and features of the present disclosure are apparent from the description and the accompanying drawings.

### BRIEF DESCRIPTION OF THE DRAWINGS

So that the manner in which the above recited features of the present disclosure can be understood in detail, a more particular description of the present disclosure, briefly summarized above, may be had by reference to embodiments. The accompanying drawings relate to embodiments of the disclosure and are described in the following. Typical embodiments are depicted in the drawings and are detailed in the description which follows.

FIG. 1 is a schematic illustration of the layout of a vacuum processing system configured to be operated according to some of the methods described herein;

FIG. 2 schematically illustrates stages (1a) and (1b) of a method of operating the vacuum processing system of FIG. 1 according to embodiments described herein;

FIG. 3 schematically illustrates subsequent stages of a method of operating the vacuum processing system of FIG. 1 according to embodiments described herein;

FIG. 4 is a schematic illustration of the layout of a vacuum processing system configured to be operated according to some of the methods described herein; and

FIG. 5 is a schematic illustration of the layout of a vacuum processing system configured to be operated according to some of the methods described herein.

### DETAILED DESCRIPTION OF EMBODIMENTS

Reference will now be made in detail to the various embodiments, one or more examples of which are illustrated in the figures. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, same reference numbers refer to the same or to similar components. Generally, only the differences with respect to the individual embodiments are described. Unless specified otherwise, the description of a part or aspect in one embodiment applies to a corresponding part or aspect in another embodiment as well.

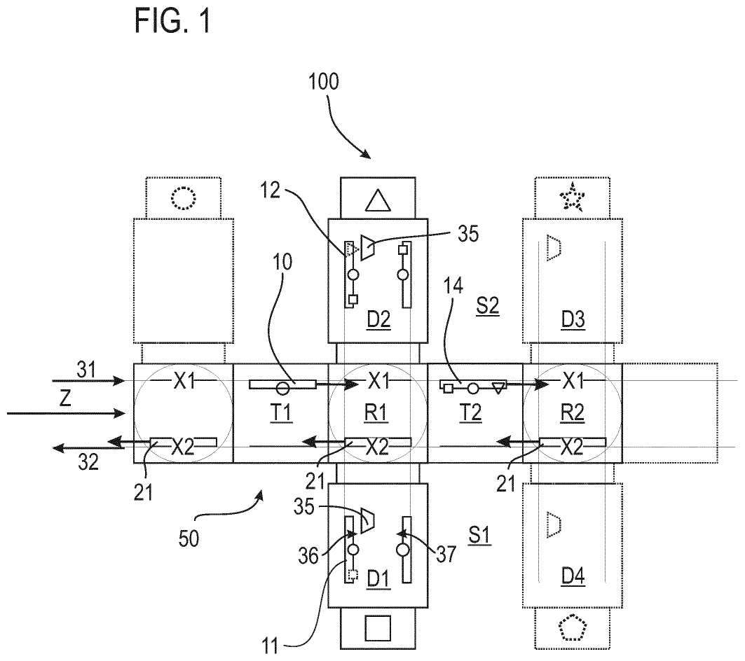

FIG. 1 is a schematic illustration of the layout of a vacuum processing system 100 configured to be operated according to some of the methods described herein.

The vacuum processing system 100 may include one or more transit modules, e.g. a first transit module T1 and a second transit module T2, and a first rotation module R1 arranged along a main transportation path 50. Further transit modules and/or further rotation modules are typically provided along the main transportation path, e.g. in an alternate arrangement. In particular, the one or more transit modules, the first rotation module R1 and optional further rotation modules may be arranged in an essentially linear setup along a direction which may be the main transportation direction Z of the vacuum processing system 100.

In some embodiments, three, four, five or more rotation modules are arranged along the main transportation path 50. Two or more deposition modules may be arranged adjacent to a rotation module, e.g. on the first side and on the second side of the main transportation path. A rotation module may be configured for routing substrates from the main transportation path into two or more deposition modules which may be arranged on the sides of the main transportation path adjacent to the rotation module.

For example, the first transit module T1 may be arranged upstream from the first rotation module R1 along the main transportation direction Z, and the second transit module T2 may be arranged downstream from the first rotation module R1 along the main transportation direction Z. Substrates to be coated may be transported in the main transportation direction Z along the main transportation path 50, i.e. from the first transit module T1 via the first rotation module R1 in the direction of the second transit module T2.

A first load lock chamber for loading substrates to be coated into the vacuum processing system may be arranged upstream from the first transit module T1, e.g. on a first end of the main transportation path, and/or a second load lock chamber for unloading coated substrates from the vacuum processing system may be arranged downstream from the second transit module T2, e.g. on a second end of the main transportation path.

In some embodiments, a return track (for example the second substrate carrier track 32 in FIG. 1) for returning empty carriers in a direction opposite to the main transport direction Z may be provided.

A transit module may be understood as a vacuum module or vacuum chamber that can be inserted between at least two other vacuum modules or vacuum chambers, e.g. between two rotation modules. Carriers, e.g. mask carriers and/or substrate carriers, can be transported through the transit module in a length direction of the transit module. The length direction of the transit module may correspond to the main transportation direction Z of the vacuum processing system. In some embodiments, two or more tracks for guiding carriers through the transit module may be provided in the transit module. For example, two substrate carrier tracks for transporting substrate carriers and two mask carrier tracks for transporting mask carriers may extend through the transit module. In some embodiments, one or more carriers may be temporarily stopped or “parked” in a transit module, until the transport of the one or more carriers through an adjacent rotation module along the main transportation path may continue.

A rotation module (also referred to herein as “routing module” or “routing chamber”) may be understood as a vacuum chamber configured for changing the orientation of one or more carriers. In particular, the transport direction of the one or more carriers may be changed by rotating one or more carriers located on tracks in the rotation module. For example, the rotation module may include a rotation device configured for rotating tracks configured for supporting carriers around a rotation axis. In some embodiments, the rotation module includes at least two tracks (first track X1 and second track X2 in FIG. 1) which may be rotated around a rotation axis. A first track X1, particularly a first substrate carrier track, may be arranged on a first side of the rotation axis, and a second track X2, particularly a second substrate carrier track, may be arranged on a second side of the rotation axis.

A rotation of the rotation module by an angle of 180° may correspond to a track switch, i.e. the position of the first track X1 and the position of the second track X2 of the rotation module may be exchanged or swapped. For example, by rotating the first rotation module R1 in FIG. 1 by an angle of 180°, a carrier can be rotated from the first substrate carrier track 31 to the second substrate carrier track 32 or vice versa.

In some embodiments, the rotation module includes four tracks, particularly two mask carrier tracks and two substrate carrier tracks which may be rotated around a rotation axis. Only the substrate carrier tracks are shown in the figures. For example, a first mask carrier track and a first substrate carrier track may be arranged adjacent to each other on a first side of the rotation axis of the rotation module, and a second mask carrier track and a second substrate carrier track may be arranged adjacent to each other on a second side of the rotation axis of the rotation module.

When a rotation module rotates by an angle of x°, e.g. 90°, a transport direction of one or more carriers arranged on the tracks may be changed by an angle of x°, e.g. 90°. A rotation of the rotation module by an angle of 180° may correspond to a track switch, i.e. the position of the first substrate carrier track of the rotation module and the position of the second substrate carrier track of the rotation module may be exchanged or swapped and/or the position of the first mask carrier track of the rotation module and the position of the second mask carrier track of the rotation module may be exchanged or swapped.

The vacuum processing system according to embodiments described herein may further include a carrier transportation system configured for transporting carriers along the main transportation path 50, e.g. in the main transportation direction Z and in an opposite direction which may be referred to herein as a “return direction”. The carrier transportation system may include a holding system, e.g. a magnetic levitation system, for lifting and holding the carriers, and a driving system for moving the carriers along tracks along a carrier transportation path.

The term “carrier” as used herein may particularly refer to a “substrate carrier” configured to hold a substrate during transport along a carrier transportation path, e.g. along a substrate carrier track. In some embodiments, the substrate may be held at the carrier in a non-horizontal orientation, particularly in an essentially vertical orientation. The term “carrier” as used herein may refer to a “mask carrier” configured to hold a mask device during the transport along a transportation path, e.g. along a mask carrier track. In some embodiments, the mask device may be held at the carrier in a non-horizontal orientation, particularly in an essentially vertical orientation.

A carrier may include a carrier body with a holding surface configured to hold a substrate or a mask device, particularly in a non-horizontal orientation, more particularly in an essentially vertical orientation. In some embodiments, the carrier body may include a guided portion configured to be guided along a carrier transportation path. For example, the carrier may be held by a holding device, e.g. by a magnetic levitation system, and the carrier may be moved by a driving device, e.g. along a mask carrier track or along a substrate carrier track.

For example, a substrate may be held at a substrate carrier by a chucking device, e.g. by an electrostatic chuck and/or by a magnetic chuck. For example, a mask device may be held at a mask carrier by a chucking device, e.g. an electrostatic chuck and/or a magnetic chuck. Other types of chucking devices may be used.

“Transporting”, “moving”, “routing” or “rotating” a substrate or a mask device as used herein may refer to a respective movement of a carrier which holds a substrate or a mask device at a holding portion of the carrier, particularly in a non-horizontal orientation, more particularly in an essentially vertical orientation.

An “essentially vertical orientation” as used herein may be understood as an orientation with a deviation of 10° or less, particularly 5° or less from a vertical orientation, i.e. from the gravity vector. For example, an angle between a main surface of a substrate (or mask device) and the gravity vector may be between +10° and −10°, particularly between 0° and −5°. In some embodiments, the orientation of the substrate (or mask device) may not be exactly vertical during transport and/or during deposition, but slightly inclined with respect to the vertical axis, e.g. by an inclination angle between 0° and −5°, particularly between −1° and −5°. A negative angle refers to an orientation of the substrate (or mask device) wherein the substrate (or mask device) is inclined downward. A deviation of the substrate orientation from the gravity vector during deposition may be beneficial and might result in a more stable deposition process, or a facing down orientation might be suitable for reducing particles on the substrate during deposition. However, also an exactly vertical orientation)(+/−1° during transport and/or during deposition is possible.

In some embodiments, a larger angle between the gravity vector and the substrate (or mask device) during transport and/or during deposition is possible. An angle between 0° and +/−80° may be understood as a “non-horizontal orientation of the mask device” as used herein. Transporting the mask device in a non-horizontal orientation may save space and allow for smaller vacuum chambers. Also a horizontal orientation of the substrate (or mask device) during transport may be possible.

A holding surface of the carrier may be essentially vertically oriented at least temporarily during the transport. Holding a large area substrate (or mask device) in an essentially vertical orientation is challenging, because the substrate (or mask device) may bend due to the weight of the substrate (mask device) or may slide down from the holding surface in the case of an insufficient grip force.

As is exemplarily depicted in FIG. 1, the vacuum processing system 100 includes a first deposition module D1 for depositing a first material which is arranged adjacent to the first rotation module R1 on a first side S1 of the main transportation path 50, and a second deposition module D2 for depositing a second material which is arranged adjacent to the first rotation module R1 on a second side S2 of the main transportation path 50 opposite the first side S1. Further deposition modules are arranged adjacent to further rotation modules.

It is to be understood that FIG. 1 may show only a small part of a vacuum processing system according to embodiments described herein. Further rotation modules, e.g. a second rotation module R2, and further deposition modules, e.g. a third deposition module D3 for depositing a third material and a fourth deposition module D4 for depositing a fourth material, may be provided. In some embodiments, the vacuum processing system 100 may be configured for depositing a layer stack on a substrate which may include, e.g., five or more subsequently deposited layers, e.g. 10 or more layers or 15 or more layers.

A “deposition module” as used herein may be understood as a section or chamber of the vacuum processing system where a material can be deposited on one or more substrates, e.g. by evaporation. A deposition source 35, e.g. a vapor source configured for directing evaporated material toward one or more substrates, is typically arranged in a deposition module. For example, the deposition source may be movable along a source transportation track which may be provided in the deposition module. The deposition source 35 may linearly move along the source transportation track while directing the evaporated material toward one or more substrates. During deposition, a mask device may be arranged in front of the substrate. Thus, the deposition module may be configured for masked deposition of a material on a substrate.

In some embodiments, which may be combined with other embodiments described herein, a deposition module may include two deposition areas, i.e. a first deposition area 36 for arranging a first substrate and a second deposition area 37 for arranging a second substrate. The first deposition area 36 may be arranged opposite the second deposition area 37 in the deposition module. The deposition source 35 may be configured to subsequently direct evaporated material toward the first substrate arranged in the first deposition area 36 and toward the second substrate arranged in the second deposition area 37. For example, an evaporation direction of the deposition source may be reversible, e.g. by rotating at least a part of the deposition source 35, e.g. by an angle of 180°.

During the deposition on a first substrate arranged in the first deposition area 36 of a deposition module, the second deposition area 37 may be used for at least one or more of: moving a second substrate to be coated into the second deposition area; moving a coated second substrate out of the second deposition area; aligning a second substrate in the second deposition area, e.g. with respect to a mask device provided in the second deposition area. Similarly, during the deposition on a second substrate arranged in the second deposition area 37 of a deposition module, the first deposition area 36 may be used for at least one or more of: moving a first substrate to be coated into the first deposition area; moving a coated first substrate out of the first deposition area; aligning a first substrate in the first deposition area, e.g. with respect to a mask device provided in the first deposition area. Accordingly, by providing two deposition areas in a deposition module, the number of coated substrates in a given time interval can be increased. Further, idle times of the deposition source can be reduced, for example, because the deposition source may not be in an idle position during the alignment of a substrate to be coated with respect to a mask, but may be used for the deposition on another substrate.

According to embodiments described herein, a method of operating a vacuum processing system 100 is described. The vacuum processing system 100 may be a vacuum processing system 100 as is schematically illustrated in FIG. 1. The vacuum processing system 100 includes a main transportation path 50 with a first rotation module R1, a first deposition module D1 and a second deposition module D2. Further rotation modules and deposition modules may be provided.

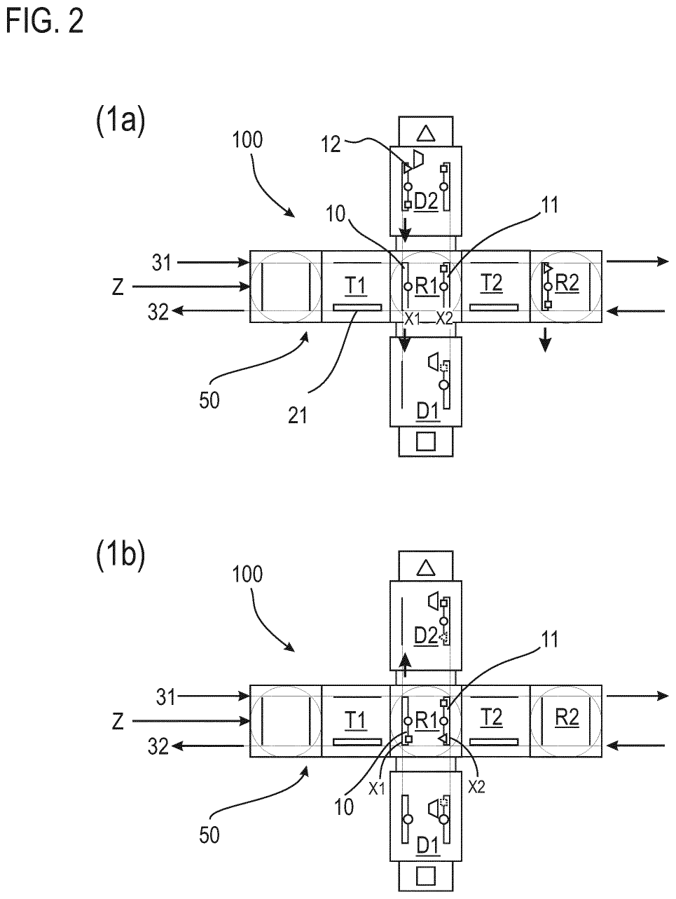

FIG. 2 schematically illustrates stages (1a) and (1b) of a method of operating the vacuum processing system of FIG. 1. In stage (1a), a substrate 10 is routed out of the main transportation path 50 into the first deposition module D1 for depositing a first material on the substrate. Later, in stage (1b), the substrate 10 is routed out of the main transportation path 50 into the second deposition module D2 for depositing the second material on the substrate 10. Later, in stage (1c), further materials may be deposited on the substrate in further deposition modules, e.g. in the third deposition module D3 and/or in the fourth deposition module D4 (not depicted in FIG. 2). For example, the substrate may subsequently be routed out of the main transportation path into the third deposition module and into the fourth deposition module. A stack with an appropriate number of materials can be deposited on the substrate.

The stages (1a), (1b), (1c) are typically carried out subsequently, e.g. with a plurality of intermediate stages therebetween, respectively. In other words, the second material may be deposited on the substrate 10 in the second deposition module D2, after the first material has been deposited on the substrate 10 in the first deposition module D1. The first material and the second material may be different organic materials.

After the deposition of each material, the substrate 10 may be moved back into the main transportation path to be routed into a subsequent deposition module from a rotation module, respectively.

The first material and the second material are different materials. In some embodiments, two or more deposition modules may be provided for depositing the same material on a substrate. For example, when the same material is deposited on a substrate in two subsequent deposition modules, a thickness of a material layer can be increased, e.g. doubled.

The first material may be a first color material of an array of pixels, e.g. a blue color material, and/or the second material may be a second color material of an array of pixels, e.g. a red color material. A third color material of the array of pixels, e.g. a green color material, may be deposited previously or subsequently. In particular, further materials may be deposited on the substrate prior to or subsequent to the first and second materials in the same vacuum processing system. At least some of the materials, e.g. the first material and the second material may be organic materials. At least one material may be a metal. For example, one or more of the following metals may be deposited in some of the deposition modules: Al, Au, Ag, Cu. At least one material may be a transparent conductive oxide material, e.g. ITO. At least one material may be a transparent material. Further rotation modules for routing the substrates into the further deposition modules may be provided upstream from and/or downstream from the first rotation module R1 along the main transportation path.

In the figures, the first material is schematically illustrated as a square, and a substrate that has been coated with the first material is depicted with a square. The second material is schematically illustrated as a triangle, and a substrate that has been coated with the first material and with the second material is depicted with a square and with a triangle. A further material, schematically illustrated as a circle, is previously deposited on the substrates. Optional further materials which are deposited on the substrates afterwards are schematically depicted as a star and as a polygon. A dashed square or a dashed triangle on a substrate stands for the respective material that is being deposited on the respective substrate during the respective stage.

The vacuum processing system according to some embodiments described herein may be a single-line-system. For example, the vacuum processing system 100 of FIG. 1 is a single-line system. Therein, the substrate and each subsequent substrate to be coated is moved into the same deposition modules in the same sequence. Said sequence may be started for subsequent substrates after predetermined time intervals, respectively, particularly after essentially constant time intervals corresponding to a tact interval of the system. For example, the substrate and each subsequent substrate to be coated may be moved in a predetermined sequence into each of the deposition modules arranged on the sides of the main transportation path. Each subsequent substrate to be coated may be moved through the deposition modules in the same predetermined sequence. A compact vacuum processing system can be provided.

In particular, in a single-line-system, the sequence (1a)-(1b)-(1c) may repeatedly start for subsequent substrates after predetermined time intervals, particularly after constant time intervals corresponding to a tact interval of the vacuum processing system, more particularly at constant tact intervals of about 60 seconds.

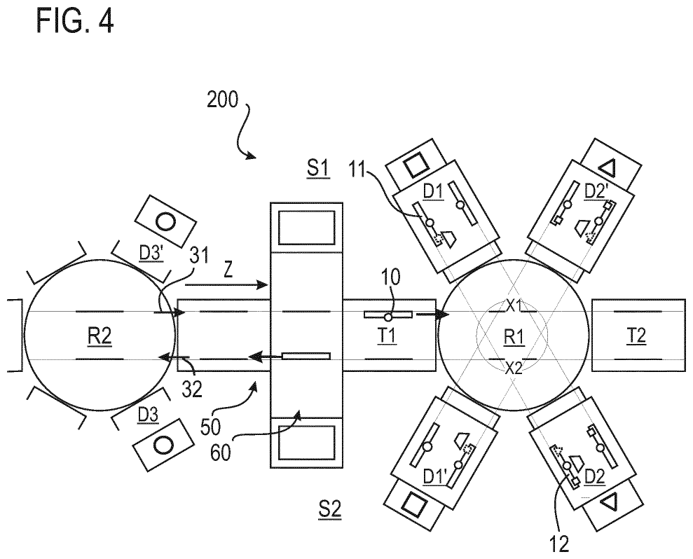

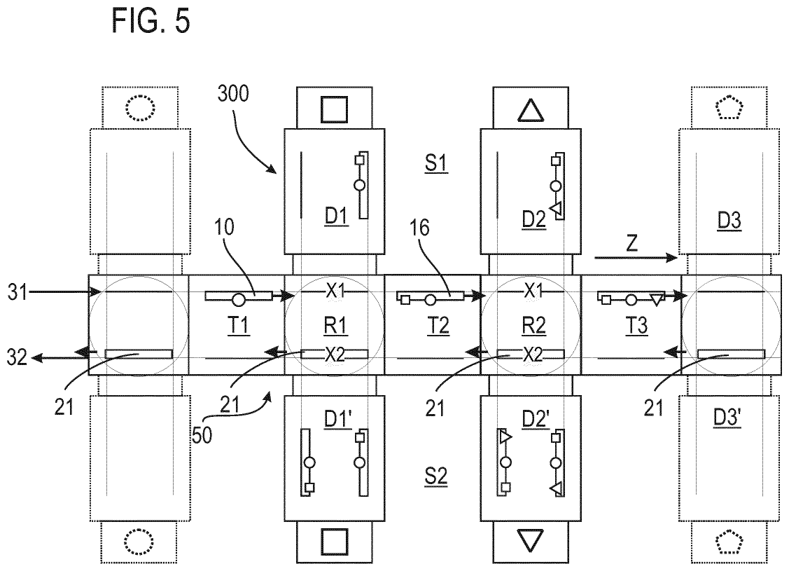

In other embodiments, a multi-line-system may be provided, e.g. a two-line-system as is exemplarily depicted in FIG. 4 and FIG. 5. Therein, a first substrate is moved into a first subset of the deposition modules in a first sequence, and a subsequent substrate to be coated is moved into a second subset of the deposition modules in a second sequence. In a two-line-system, a second subsequent substrate to be coated is again moved into the first subset of the deposition modules in the first sequence, and a third subsequent substrate to be coated is again moved into the second subset of the deposition modules in the second sequence. In other words, two coating lines (a first coating line and a second coating line) are provided in the same vacuum processing system for alternately coating subsequent substrates. The first sequence (i.e. the movement of a substrate along the first coating line) may be started for a respective substrate to be coated after predetermined time intervals which may correspond to twice the tact interval of the whole system, and the second sequence (i.e. the movement of a substrate along the second coating line) may be started for a respective substrate after predetermined time intervals which may correspond to twice the tact interval of the whole system. In other words, the two coating lines in combination may provide the overall tact time of the whole system, whereas each of the two coating lines may start a new coating sequence every second tact interval of the whole system.

In a multi-line-system, the substrate 10 is moved into only a part of the deposition modules for being coated, particularly into only half the deposition modules, and a subsequent substrate is moved into only another part of the deposition modules for being coated, particularly into the other half of the deposition modules.

Moving the substrate 10 along the main transportation path 50 may include a movement of a substrate carrier which holds the substrate 10 along the main transportation path 50, e.g. from the first transit module T1 into the first rotation module R1, as is schematically by an arrow in FIG. 1. The substrate 10 may already be coated with one or more materials (illustrated by a circle in FIG. 1). During the movement of the substrate 10, the substrate may be carried by a substrate carrier, particularly, in a non-horizontal orientation, more particularly in an essentially vertical orientation.

As is schematically depicted by respective arrows in FIG. 1, a plurality of substrates arranged along the main transportation path 50 may be moved synchronously along the main transportation path 50. For example, substrate carriers which are arranged on the first substrate carrier track 31 may be moved synchronously in the main transport direction Z into a respective adjacent module, and/or the substrate carriers which are arranged on the second substrate carrier track 32 (also referred to herein as a “return track”) may be synchronously moved in an opposite direction (also referred to herein as a “return direction”) into a respective adjacent module. “Synchronously” as used herein may be understood as “within the same time window” of, e.g. 10 seconds or less, particularly about 5 seconds.

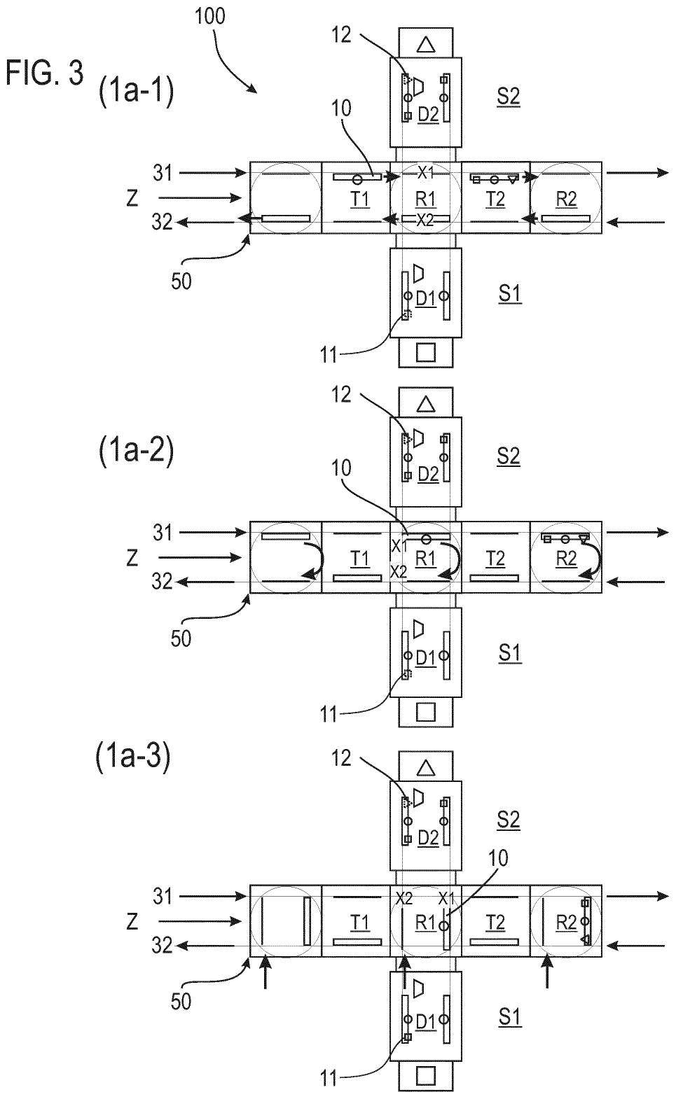

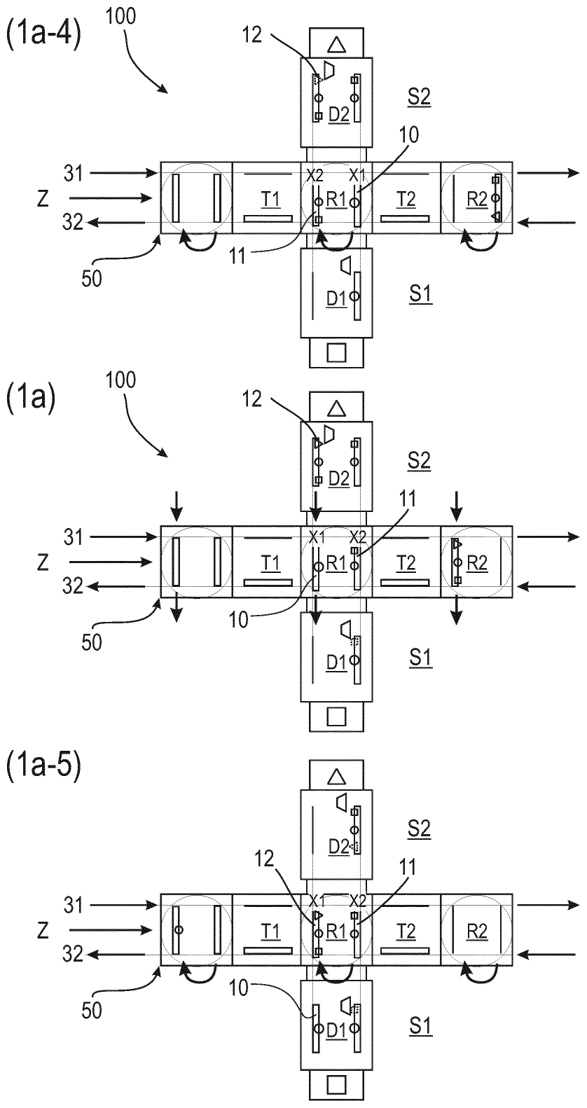

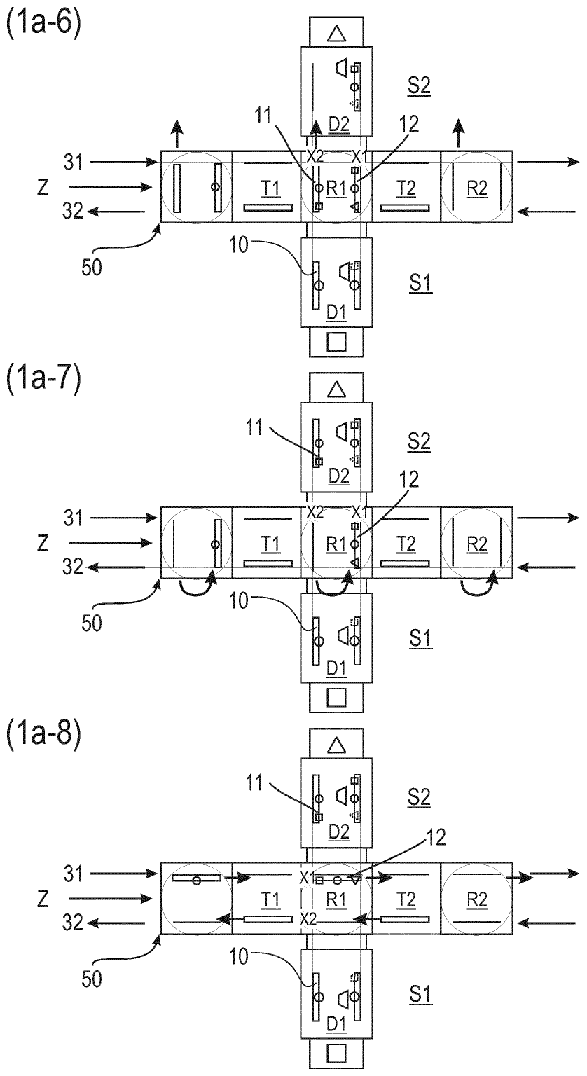

In particular, in some embodiments, time intervals in which the rotation modules are arranged in the orientation of the main transportation path may be used for synchronously returning empty carriers 21 along the return track in the return direction. In time intervals in which the rotation modules are in a rotated state, the empty carriers may wait in respective transit modules until the next synchronous movement along the main transportation path 50 is possible. Two adjacent empty carriers along the return track may be temporally delayed by one tact interval. In other words, a subsequent empty carrier may be at the position of the previous empty carrier one tact interval later, e.g. 60 seconds later (see also stages (1a-1) to (1a-8) of FIG. 3).

Similarly, two substrate carriers which are arranged on the first substrate carrier track 31 may by temporarily delayed by a multiple of one tact interval. For example, the substrate 10 and the fourth substrate 14 which are arranged on the first substrate carrier track 31 in FIG. 1 may be temporarily delayed by five tact intervals. In other words, the substrate 10 will be at the position of the fourth substrate 14 five tact intervals later, e.g. about 300 seconds later. At that time, the substrate 10 will be coated with both the first material and the second material, as is the fourth substrate 14 at that position in the system.

A synchronous movement of carriers along the main transportation path 50 simplifies the carrier traffic in the vacuum processing system so that the tact intervals can be reduced and coated substrates can be provided at a smaller tact time.

It is to be noted that the main transportation path 50 may have a non-linear setup in some embodiments, and the linear setup depicted in FIG. 1 is only an example. The main transportation path 50 can be understood as a path along which the substrates are transported, and which includes one or more branching points, typically provided by respective rotation modules, at which the substrates can be routed out of the main transportation path for being coated with a material in one or more deposition modules. Further, at the one or more branching points, the substrates can be routed back into the main transportation path for continuing with the transport of the substrates along the main transportation path.

As is schematically depicted in stage (1a) of FIG. 2, the routing of the substrate 10 out of the main transportation path 50 may include moving the substrate 10 out of the main transportation path 50 into the first deposition module D1 and/or into the second deposition module D2 from a first rotation module R1 which may be used for changing the transport direction of the substrate 10. In particular, the substrate 10 may enter the first rotation module R1 in the main transportation direction Z and may leave the first rotation module R1 toward the first deposition module D1 or toward the second deposition module D2 in a second direction, which may be perpendicular to the main transportation direction Z. For example, the first rotation module R1 may be used for rotating the substrate 10 by an angle of about 90°.

In some embodiments, the substrate 10 is moved into the first deposition module D1 from the first rotation module R1, as is schematically depicted in stage (1a) of FIG. 2. After the deposition of the first material on the substrate 10 in the first deposition module D1 (illustrated by a square), the substrate 10 may be moved back into the first rotation module R1.

In stage (1b), the substrate 10 may be moved into the second deposition module D2 from the first rotation module R1 in order to be coated with the second material in the second deposition module D2, as is schematically depicted in stage (1b) of FIG. 2. After the deposition of the second material on the substrate 10, the substrate 10 may be moved back into the first rotation module R1. Thereafter, the first rotation module R1 may rotate the substrate 10 back to the main transportation direction Z, and the transport of the substrate along the main transportation path 50 may continue.

In some embodiments, the first rotation module R1 is arranged in the main transportation path 50. Further rotation modules, e.g. a second rotation module R2, may be arranged in the main transportation path downstream from the first rotation module R1, e.g. for routing the substrate out of the main transportation path 50 into further deposition modules to be coated with further materials.

The routing of the substrate 10 out of the main transportation path 50 into the first deposition module D1 and afterwards into the second deposition module D2 for depositing different materials on the substrate simplifies the substrate traffic in the vacuum processing system. Accordingly, the tact interval of the deposition process can be reduced, and a higher number of substrates can be coated with a plurality materials in a given time period. In other words, coated substrates can be provided at a smaller tact time.

The first rotation module R1 and/or every further rotation module may include a first track X1 arranged on a first side of a rotation axis of the first rotation module R1, and a second track X2 arranged on a second side of the rotation axis of the first rotation module R1. In stage (1a), the substrate 10 may be arranged on the first track X1 of the first rotation module R1, as is schematically depicted in stage (1a) of FIG. 2.

During the movement of the substrate 10 into the first rotation module R1 on the first track X1, the second track X2 of the first rotation module R1 may be empty. Alternatively, the second track X2 of the first rotation module R1 may be occupied. For example, as is schematically depicted in FIG. 1, an empty carrier 21 may be moved from the second track X2 in the same time period. The empty carrier 21 may be directed along the second substrate carrier track 32 in a direction opposite to the main transport direction Z, e.g. to be loaded with a new substrate to be coated.

According to some embodiments, which may be combined with other embodiments described herein, in stage (1a), a second substrate 11 may be arranged on the second track X2 of the first rotation module R1 during a time period in which the substrate 10 is moved out of the first rotation module R1 into the first deposition module D1 from the first track X1 of the rotation module R1. The second substrate 11 is schematically depicted in stage (1a) of FIG. 2.

The second substrate 11 may be a substrate which has been coated with the first material in the first deposition module D1 prior to the substrate 10. After the deposition of the first material on the second substrate 11, the second substrate 11 may be moved from the first deposition module D1 onto the second track X2 of the first rotation module R1, particularly while the first track X1 may already be occupied with the substrate 10. Subsequently, the first rotation module R1 may be rotated, and the substrate 10 may be moved from the first track X1 into the first deposition module D1, as is schematically depicted in stage (1a) of FIG. 2. Accordingly, the exchange of the second substrate 11 and the substrate 10 in the first deposition module D1 can be accelerated and the tact interval of the deposition process can be reduced.

In particular, the second substrate 11 and the substrate 10 may both be coated in the same deposition area of the first deposition module D1, e.g. in the left deposition area in FIG. 2. The substrate exchange in said deposition area can be accelerated by simultaneously arranging the substrate 10 and the second substrate 11 in the first rotation module R1 for the exchange of the substrates, as is schematically depicted in stage (1a) of FIG. 2.

According to some embodiments, which may be combined with other embodiments described herein, in stage (1a), a third substrate 12 may be moved into the first rotation module R1 from a second deposition module D2 during a time period in which the substrate 10 is moved out of the first rotation module R1 into the first deposition module D1. The third substrate 12 is schematically depicted in stage (1a) of FIG. 2.

In particular, the third substrate 12 may be moved into the first rotation module R1 on the first track X1 synchronously with or directly subsequent to the movement of the substrate 10 out of the first rotation module R1 from the first track X1 into the first deposition module D1. For example, the movements of the third substrate 12 and of the substrate 10 may happen within a time window of ten seconds or less, particularly about five seconds, as is schematically illustrated by respective arrows in stage (1a) of FIG. 2.

Accordingly, the first track X1 of the first rotation module R1 may be used immediately afterwards for the rotation of the third substrate 12, which may be a substrate that has already been coated with the first material in the first deposition module D1 and with the second material in the second deposition module D2 (illustrated by the square and the triangle). The third substrate 12 may be routed back into the main transportation path 50.

The first deposition module D1 may be arranged on an opposite side of the first rotation module R1 with respect to the second deposition module D2. The first rotation module R1 may be used for a substrate transport between the first deposition module D1 and the second deposition module D2. The utilization of the first rotation module R2 can be improved and the tact time of the deposition process can be reduced.

In a first rotation position of a rotation module that is depicted in FIG. 1, the first track X1 and the second track X2 may be arranged to connect an upstream side of the main transportation path 50 with a downstream side of the main transportation path 50. Accordingly, substrates may be routed through the rotation module along the main transportation path 50. For example, an empty carrier 21 can be moved through the rotation module in a return direction, e.g. along the second substrate carrier track 32.

Alternatively or additionally, in a second rotation position of the rotation module (e.g. after a counterclockwise rotation by 90° from the first rotation position as schematically depicted in stage (1a) of FIG. 2), the first track X1 of the first rotation module R1 may connect a first deposition area of the first deposition module D1 with a first deposition area of the second deposition module D2, and/or the second track X2 of the first rotation module may connect a second deposition area of the first deposition module D1 with a second deposition area of the second deposition module.

Alternatively of additionally, in a third rotation position (e.g. after a rotation by 180° from the first rotation position), the first track X1 and the second track X2 may be arranged to connect the upstream side of the main transportation path 50 with the downstream side of the main transportation path 50. However, the positions of the first track X1 and of the second track X2 may be swapped.

Alternatively or additionally, in a fourth rotation position of the rotation module (e.g. after a clockwise rotation by 90° from the first rotation position), the first track X1 of the first rotation module may connect the second deposition area of the first deposition module D1 with the second deposition area of the second deposition module D2, and/or the second track X2 of the first rotation module may connect the first deposition area of the first deposition module D1 with the first deposition area of the second deposition module. In other words, the position of the first track X1 and of the second track X2 may be swapped with respect to the second rotation position.

FIG. 3 shows a more detailed sequence of subsequent stages of a method of operating a vacuum processing system. A time interval of 3 seconds or more and 8 seconds or less may pass between two subsequent stages of FIG. 3. The illustrated sequence may be utilized (i) for transferring a substrate 10 from the main transportation path 50 into the first deposition module D1 to be coated with the first material, (ii) for transferring a second substrate 11 that has been coated with the first material from the first deposition module D1 into the second deposition module D2, and (iii) for transferring a third substrate 12 that has been coated with both the first material and the second material from the second deposition module D2 back into the main transportation path 50.

The second substrate 11 may be a substrate that is coated with the first material two or four tact intervals before the substrate 10. The third substrate 12 may be a substrate that is coated with the first material two or four tact intervals before the second substrate 11. In other words, the substrate 10, the second substrate 11, and the third substrates may be temporarily delayed by a multiple of one tact interval, particularly by two or four tact intervals.

According to some embodiments, in stage (1a-1), the substrate 10 is moved along the main transportation path 50 onto the first track X1 of the first rotation module R1. At that time, the second substrate 11 may be coated with the first material in the first deposition module D1, and the third substrate 12 may be coated with the second material in the second deposition module D2.

Thereafter, in a stage (1a-2), the first rotation module R1 may be rotated by a first angle, e.g. clockwise by an angle of 90°. For example, the first rotation module R1 may be rotated from the first rotation position to the fourth rotation position. At that time, the deposition of the first material on second substrate 11 in the first deposition module D1 may be almost or already finished. The deposition of the second material on third substrate 12 in the second deposition module D2 may not yet be finished. For example, the deposition of the first material on the second substrate 11 in the first deposition module D1 and the deposition of the second material on the third substrate 12 may not exactly run in parallel, but with a small time shift of, e.g. 10 or more seconds, therebetween. Said small time shift may correspond to the time that is used for two rotations of a rotation module.

It is to be noted that, in some embodiments, the deposition processes in deposition modules arranged on the first side S1 of the main transportation path may be synchronized, and the deposition processes in deposition modules arranged on the second side S2 of the main transportation path may be synchronized, respectively. There may be a small time shift between the deposition processes in the deposition modules arranged on the first side S1 and the deposition processes in the deposition modules arranged on the second side S2.

In some embodiments, the first angle may be)+90° (−270° or) −90° (+270°, depending on the arrangement of the first and second deposition modules on the first and second sides of the main transportation path. It is to be noted that the first angle can be any angle, depending on an orientation of the respective deposition modules with respect to the main transportation path. For example, in the embodiment depicted in FIG. 4, the first angle may be −60°, +60°, +120° or −120°, according to the orientations of the deposition modules with respect to the main transportation path 50.

In some embodiments, which may be combined with other embodiments described herein, all rotation modules arranged along the main transportation path 50 of the vacuum processing system may be rotated synchronously. In particular, substrates which are time-shifted by a given multiple of one tact interval, may synchronously change their respective positions or orientations in various modules of the vacuum processing system (illustrated by rotation arrows in each rotation module of the system in stage (1a-2)). For example, the substrates which are being synchronously rotated in the rotation modules in stage (1a-2) of FIG. 3, may be time-shifted by five tact intervals, respectively.

Thereafter, in a stage (1a-3), the second substrate 11 may be moved from the first deposition module D1, particularly from the first deposition area of the first deposition module D1, onto the second track X2 of the first rotation module R1 which may be unoccupied.

Thereafter, in stage (1a-4), the first rotation module R1 may be rotated by a second angle, particularly by 180°. For example, the first rotation module R1 may be rotated from the fourth rotation position to the second rotation position. At that time, the deposition of the second material on third substrate 12 in the second deposition module D2 may be almost or already finished.

In some embodiments, all rotation modules arranged along the main transportation path of the vacuum processing system may be rotated synchronously in stage (1a-4). In particular, substrates which are time-shifted by a given multiple of one tact interval, may synchronously change their respective positions or orientations in various modules of the vacuum processing system (illustrated by rotation arrows in each rotation module of the system in stage (1a-4)).

Thereupon, in stage (1a), the substrate 10 may be moved into the first deposition module D1 from the first track X1, particularly into the first deposition area of the first deposition module D1.

In some embodiments, while the substrate 10 is moved in stage (1a) into the first deposition module D1, the second track X2 may be occupied by the second substrate 11 that is to be routed into the second deposition module D2. Accordingly, the utilization of the first rotation module R1 can be improved and the cycle interval of the deposition process can be reduced.

In some embodiments, which may be combined with other embodiments described herein, in stage (1a), the third substrate 12 may be moved onto the first track X1 of the first rotation module R1 from a second deposition module D2, particularly from a first deposition area of the second deposition module D2, simultaneously with or directly subsequent to the movement of the substrate 10 from the first track X1 into the first deposition module D1. Accordingly, the first track X1 of the first rotation module R1 can be used right away for routing the third substrate 12 back into the main transportation path 50.

In some embodiments, which may be combined with other embodiments described herein, the method may include, in a stage (1a-5), rotating the first rotation module R1 by a third angle, particularly by 180°. For example, the positions of the first track X1 which is occupied by the third substrate 12 and of the second track X2 which is occupied by the second substrate 11 may be swapped. In particular, the first rotation module R1 may be rotated from the second rotation position to the fourth rotation position.

In some embodiments, all rotation modules arranged along the main transportation path of the vacuum processing system may be rotated synchronously in stage (1a-5). In particular, substrates which are time-shifted by a given multiple of one tact interval, may synchronously change their respective positions or orientations in various analogue modules of the vacuum processing system (illustrated by rotation arrows in each rotation module of the system in stage (1a-5)).

Subsequently, in stage (1a-6), the second substrate 11 may be moved from the second track X2 of the first rotation module R1 into the second deposition module D2 to be coated with the second material. At that time, the first track X1 may be occupied by the third substrate 12.

Subsequently, in stage (1a-7), the first rotation module R1 may be rotated by a fourth angle, e.g. by −90° or +90°. In particular, the first rotation module R1 may be rotated from the fourth rotation position to the first rotation position.

In some embodiments, all rotation modules arranged along the main transportation path of the vacuum processing system may be rotated synchronously in stage (1a-7). In particular, substrates which are time-shifted by a given multiple of one tact interval, may synchronously change their respective positions or orientations in various analogue modules of the vacuum processing system (illustrated by rotation arrows in each rotation module of the system in stage (1a-7).

Thereupon, in stage (1a-8), the third substrate 12 may be moved out of the first rotation module R1 along the main transportation path 50, particularly from the first track X1.

In some embodiment, substrate movements in corresponding modules of the vacuum processing system may be synchronized. For example, substrate movements in rotation modules may be synchronized, substrate movements in deposition modules arranged on the first side S1 may be synchronized, and/or substrate movements in deposition modules arranged on the second side S2 may be synchronized. Substrates which are time-shifted by a given multiple of one tact interval and which are arranged in corresponding modules may be moved, e.g. translated or rotated, synchronously, i.e. with the same time interval of, e.g. ten seconds or less or within about five seconds. The substrate traffic in the vacuum processing system can be simplified and the tact interval can be reduced.

The method may further include moving the substrate 10 from the first deposition module D1 back into the first rotation module R1 after the deposition of the first material on the substrate 10 in the first deposition module D1, particularly two tact intervals after stage (1a-3).

Thereafter, the first rotation module R1 may be rotated one or more times, particularly including two times by an angle of 180°, particularly two tact intervals after stages (1a-4) and (1a-5), respectively.

Thereafter, in stage (1b), the substrate 10 may be moved into the second deposition module D2, particularly into the first deposition area of the second deposition module D1, for depositing the second material on the substrate. Stage (1b) may be carried out two tact times after stage (1a-6).

In a single-line-system as exemplarily illustrated in FIGS. 1 to 3, the movement sequence of moving the substrate 10 from the first deposition module D1 into the second deposition module D2 may be carried out two tact intervals after the movement of the second substrate 11 from the first deposition module D1 into the second deposition module D2. In particular, two tact intervals after the above movement sequence (1a-1)-(1a-2)-(1a-3)-(1a-4)-(1a)-(1a-5)-(1a-6)-(1a-7)-(1a-8), a corresponding movement sequence may be carried out, wherein the substrate of the above movement sequence is the second substrate of the corresponding movement sequence, and wherein the second substrate of the above movement sequence is the third substrate of the corresponding movement sequence. Accordingly, each substrate may be moved into the respective next deposition module every two tact intervals.

In some embodiments, the transfer time of a substrate from one module to an adjacent module may be between 3 seconds and 10 seconds, particularly about 5 seconds. In some embodiments, the time for rotating a rotation module between two rotation positions may be between 3 seconds and 10 seconds, particularly about 5 seconds.

In some embodiments, the sequence (1a)-(1b)-(1c) repeatedly starts for subsequent substrates after predetermined time intervals, particularly after constant time intervals corresponding to tact intervals of the vacuum processing system, more particularly at constant tact intervals of about 60 seconds.

In some embodiments, in stages (1a) of sequences started at even tact intervals, a substrate may be routed into a first deposition area of the first deposition module D1 for depositing the first material on the substrate, and, in stages (1a) of sequences started at odd tact intervals, a respective substrate may be routed into a second deposition area of the first deposition module D1 for depositing the first material on the substrate.

Similarly, in stages (1b) of sequences started at even tact intervals, a respective substrate may be routed into a first deposition area of the second deposition module D2 for depositing the second material on the substrate, and in stages (1b) of sequences started at odd tact intervals, a respective substrate may be routed into a second deposition area of the second deposition module D2 for depositing the second material on the substrate.

Similarly, in stages (1c) of sequences started at even tact intervals, respective substrates may be routed into respective first deposition areas, and, in stages (1c) of sequences started at odd tact intervals, respective substrates may be routed into respective second deposition areas.

For example, a first sequence (1a)-(1b)-(1c) may start with stage (1a) at a tact interval 0, in which a substrate is routed into the first deposition area of the first deposition module D1.

A second sequence (1a)-(1b)-(1c) may start with stage (1a) one tact interval later (at an odd tact interval), in which a subsequent substrate is routed into the second deposition area of the first deposition module D1. At that time, the first deposition area of the first deposition module D1 may still be occupied with the substrate of the first sequence, which may be aligned or coated in the first deposition area.

A third sequence (1a)-(1b)-(1c) may start with stage (1a) on tact interval later (at an even tact interval), in which a second subsequent substrate is routed into the first deposition area of the first deposition module D1. At that time, the substrate of the first sequence may already have left the first deposition area and may be headed toward the second deposition area of the second deposition module D2.

A fourth sequence (1a)-(1b)-(1c) may start with stage (1a) one tact interval later (at an odd tact interval), in which a third subsequent substrate is routed into the second deposition area of the first deposition module D1. At that time, the second substrate of the second sequence may already have left the second deposition area of the first deposition module D1 and may be headed toward the second deposition area of the second deposition module D2.

Subsequent sequences (also referred to herein as cycles) may be repeatedly started after predetermined time intervals which may correspond to the tact interval of the vacuum processing system.

In particular, the sequence (1a)-(1b)-(1c) may be repeatedly started for subsequent substrates after respective time intervals, particularly at constant time intervals which may correspond to the tact interval of the system. The tact interval may be 45 seconds or more and/or 120 seconds or less, particularly about 60 seconds.

The deposition in subsequent cycles may alternately be performed in the first deposition areas of the deposition modules and in the second deposition areas of the deposition modules. Every second cycle may involve a movement sequence into the corresponding deposition areas of the deposition modules of the system.

When the sequence (1a)-(1b)-(1c) is repeatedly started for subsequent substrates after constant time intervals corresponding to the tact interval, a substrate with a deposited layer stack can be provided after every tact time of, e.g. every 45 seconds or more and/or 120 seconds or less, particularly about every 60 seconds.

The vacuum processing system 100 of FIG. 1 may be operated according to one or more of the following parameters: the time for rotating a rotation module between two rotation positions may be 3 seconds or more and 10 seconds or less, particularly about 5 seconds; the time for moving a carrier from a vacuum module to an adjacent vacuum module may be 3 seconds or more and 10 seconds or less, particularly about 5 seconds; all rotation modules of the system may be synchronized; a forward and a backward transport of substrates along the main transportation path may be possible at the same time; the time intervals between subsequent substrate exchanges may be 60 seconds; accordingly, the overall tact interval of the system may be 60 seconds, as the system is configured as a single-line-system.

According to some embodiments, which may be combined with other embodiments described herein, the main transportation path 50 may include a first substrate carrier track 31 and a second substrate carrier track 32 arranged parallel to each other. The first substrate carrier track 31 and the second substrate carrier track 32 may be configured for transporting substrate carriers along the main transportation path 50. The substrates may be moved along the first substrate carrier track 31 in the main transportation direction Z while being held by substrate carriers.

In some embodiments, empty carriers may be returned along the second substrate carrier track 32 in an opposite direction, i.e. in a direction opposite to the main transportation direction Z (also referred to herein as a “return direction”). An empty carrier may be understood as a carrier which does not hold a substrate or a mask device. Accordingly, the substrates are transported while being held by substrate carriers along the first substrate carrier track 31 in the main transportation direction Z, are detached from the substrate carriers at an end of the main transportation path 50 and unloaded from the system, and the empty carriers can be returned along the second substrate carrier track 32 in the return direction. New substrates to be coated can be loaded onto the empty substrate carriers.

The method according to embodiments described herein may be carried out in the vacuum processing system 100 depicted in FIG. 1. The vacuum processing system 100 may include one or more transit modules and a first rotation module R1 provided along the main transportation path 50, the first deposition module D1 for depositing the first material which is arranged adjacent to the first rotation module R1 on a first side S1 of the main transportation path 50, and the second deposition module D2 for depositing the second material which is arranged adjacent to the first rotation module R1 on a second side S2 of the main transportation path 50 opposite the first deposition module D1.

In some embodiments, which may be combined with other embodiments described herein, one or more mask carrier tracks (not shown in the figures) may be provided which extend along the main transportation path 50, particularly parallel to the one or more substrate carrier tracks. Accordingly, in some embodiments, two mask carrier tracks and two substrate carrier tracks may extend along the main transportation path 50, e.g. through the transit modules and rotation modules along the main transportation path.

Mask carriers holding mask devices may be transported along the one or more mask carrier tracks of the vacuum processing system. In particular, a mask device may be held at a mask carrier in a non-vertical orientation, particularly in an essentially vertical orientation.

In some embodiments, a mask device may include a mask and a mask frame. The mask frame may be configured to stabilize the mask which is typically a delicate component. For example, the mask frame may surround the mask in the form of a frame. The mask may be permanently fixed to the mask frame, e.g. by welding, or the mask may be releasably fixed to the mask frame. A circumferential edge of the mask may be fixed to the mask frame.

The mask may include a plurality of openings formed in a pattern and configured to deposit a corresponding material pattern on a substrate by a masked deposition process. During deposition, the mask may be arranged at a close distance in front of the substrate or in direct contact with the front surface of the substrate. For example, the mask may be a fine metal mask (FMM) with a plurality of openings, e.g. 100.000 openings or more. For example, a pattern of organic pixels may be deposited on the substrate. Other types of masks are possible, e.g. edge exclusion masks.

In some embodiments, the mask device may be at least partially made of a metal, e.g. of a metal with a small thermal expansion coefficient such as invar. The mask may include a magnetic material so that the mask can be magnetically attracted toward the substrate during deposition. Alternatively or additionally, the mask frame may include a magnetic material so that the mask device can be attracted to a mask carrier via magnetic forces.

The mask device may have an area of 0.5 m² or more, particularly 1 m² or more. For example, a height of the mask device may be 0.5 m or more, particularly 1 m or more, and/or a width of the mask device may be 0.5 m or more, particularly 1 m or more. A thickness of the mask device may be 1 cm or less, wherein the mask frame may be thicker than the mask.

The mask device may be held by a mask carrier during the transport in the vacuum processing system 100. For example, the mask carrier which holds the mask device may be transported along the main transportation path 50 in the vacuum processing system 100. In some embodiments, the mask carrier may be guided along mask carrier tracks through the vacuum processing system. For example, the mask carrier may include a guided portion configured to be guided along the mask carrier tracks.

In some embodiments, the mask carrier is transported by a transportation system, which may include a magnetic levitation system. For example, a magnetic levitation system may be provided so that at least a part of the weight of the mask carrier may be carried by the magnetic levitation system. The mask carrier can then be guided essentially contactlessly along the mask carrier tracks through the vacuum processing system. A drive for moving the carrier along the mask carrier tracks may be provided.

It may be beneficial to exchange used mask devices at predetermined time intervals with cleaned or new mask devices in the respective deposition modules. For example, a mask device may be used for the deposition of a material on a given number of substrates, e.g. 10 substrates or more and 100 substrates or less, before an exchange of the mask device may be reasonable.

For exchanging a used mask device, the used mask device may be routed from a deposition module into the main transportation path, and a mask device to be used may be routed from the main transportation path into the deposition module.

For example, a mask device to be used may be transported along the main transportation path 50 on one of the mask carrier tracks, particularly adjacent to and/or synchronously with a substrate that may be transported in parallel on one of the substrate carrier tracks. The mask device to be used and the substrate may be rotated together and/or moved together into the first rotation module.

In stage (1a), the mask device to be used may be routed out of the main transportation path 50 into a first deposition area of the first deposition module D1 for masked deposition on the substrate 10, particularly together with the substrate 10.

In other words, a mask device to be used may be moved into a deposition area together with a substrate to be coated. In particular, the first rotation module R1 may be used for routing a mask device to be used synchronously with a substrate that is to be coated into a deposition area of a deposition module. The mask exchange can be accelerated and the tact time of the vacuum processing system can be reduced.

Mask devices may be exchanged less frequently than substrates. Accordingly, a mask device may be routed into a deposition module together with a substrate not with every substrate exchange in a deposition module, but only, e.g., in every tenth cycle, in every twentieth cycle or even less frequently.

In some embodiments, used mask devices may be routed out of the first deposition area (or of any other deposition area) and mask devices to be used may be routed into the first deposition area (or in any other deposition area) at a predetermined mask exchange frequency that may be lower than a substrate exchange frequency in the first deposition area (or any other deposition area). For example, a mask device may be exchanged with every tenth substrate exchange, every twentieth substrate exchange or even less frequently in a given deposition area.

FIG. 4 shows a vacuum processing system 200 according to some embodiments described herein in a schematic view. The vacuum processing system 200 can be used to carry out some of the methods described herein. In particular, the vacuum processing system 200 can be used for carrying out any of the methods explained above, so that reference can be made to the above explanations which are not repeated here.

The vacuum processing system 200 may include one or more transit modules, e.g. a first transit module T1 and a second transit module T2, and a first rotation module R1 provided along the main transportation path 50. Further transit modules and/or further rotation modules may be arranged along the main transportation path, as is schematically indicated in FIG. 4.

The vacuum processing system 200 may further include a first deposition module D1 for depositing the first material which is arranged adjacent to the first rotation module R1 on a first side S1 of the main transportation path 50, and a second deposition module D2 for depositing the second material which is arranged adjacent to the first rotation module R1 on a second side S2 of the main transportation path 50 opposite the first side S1.

The first deposition module D1 and the second deposition module D2 may be arranged opposite each other on different sides of the first rotation module R1, i.e. at an angle of 180° with respect to the rotation axis of the first rotation module R1. Accordingly, the first track X1 and the second track X2 of the first rotation module R1 may connect the deposition areas of the first deposition module D1 and the second deposition module D2 in at least one rotation position of the first rotation module.

As is depicted in FIG. 4, in some embodiments, a second-line first deposition module D1′ for depositing the first material may be arranged adjacent to the first rotation module R1 on the second side S2 (or, alternatively, on the first side S1) of the main transportation path 50. Yet further, a second-line second deposition module D2′ for depositing the second material may be arranged adjacent to the first rotation module R1 on the first side S1 (or, alternatively, on the second side S2) of the main transportation path 50.

The second-line first deposition module D1′ and the second-line second deposition module D2′ may be arranged opposite each other on different sides of the first rotation module R1, i.e. at an angle of 180° with respect to the rotation axis of the first rotation module R1. Accordingly, the first track X1 and the second track X2 of the first rotation module R1 may connect the deposition areas of the second-line first deposition module D1′ and the second-line second deposition module D2′ in at least one rotation position of the first rotation module.

Further deposition modules and corresponding second-line deposition modules may be arranged adjacent to further rotation modules provided along the main transportation path 50. For example, a mirror-line setup may be provided which has an essentially symmetric configuration with respect to the main transportation path 50. In other words, each deposition module configured for depositing a material may be arranged symmetrically to a corresponding second-line deposition module configured for depositing the same material on the other side of the main transportation path. For example, a third deposition module D3 for depositing a third material may be arranged symmetrically to a second-line third deposition module D3′ for depositing the third material on the other side of the main transportation path 50, as is schematically depicted in FIG. 4. Both the third deposition module D3 and the second-line third deposition module D3′ may be arranged adjacent to a second rotation module R2.

The first rotation module R1 may be configured for routing carriers between an upstream portion of the main transportation path 50, a downstream portion of the main transportation path 50, the first deposition module D1 (particularly, first and second deposition areas of the first deposition module D1), the second deposition module D2 (particularly, first and second deposition areas of the second deposition module D2), the second-line first deposition module D1′ (particularly, first and second deposition areas of the second-line first deposition module D1′), and/or the second-line second deposition module D2′ (particularly, first and second deposition areas of the first deposition module D2′).

For example, the first rotation module R1 may include a first track X1 and a second track X2 which are rotatable around a rotation axis that is arranged between the first track X1 and the second track X2. The first rotation module R1 may be rotatable between at least six rotation positions, wherein two rotation positions may be provided for connecting the upstream portion of the main transportation path 50 with the downstream portion of the main transportation path 50, two rotation positions may be provided for connecting the first deposition module D1 with the second deposition module D2, and two rotation positions may be provided for connecting the second-line first deposition module D1′ with the second-line second deposition module D2′.

An angle between the main transportation path 50 and the first deposition module D1 may be about 60°, an angle between the main transportation path 50 and the second deposition module D2 may be −120°, an angle between the main transportation path 50 and the second-line first deposition module D2 may be −60°, and an angle between the main transportation path 50 and the second-line second deposition module D2′ may be +120°. Other angles are possible. In particular, the deposition areas of the first deposition module D1 and of the second deposition module D2 may be aligned on opposite sides of the first rotation module such as to be connectable via the first and second tracks of the first rotation module in at least one rotation position, and the deposition areas of the second-line first deposition module D1′ and of the second-line second deposition module D2′ may be aligned on opposite sides of the first rotation module such as to be connectable via the first and second tracks of the first rotation module R1 in at least one rotation position.

The vacuum processing system 200 of FIG. 4 has a two-line configuration as explained above. Therein, every second substrate (e.g., substrates of sequences (1a)-(1b)-(1c) started at even tact intervals) is subsequently moved into a first subset of the deposition modules including the first deposition module D1, the second deposition module D2 and at least one further deposition module, but not into the second subset of deposition modules. The other substrates (e.g., substrates of sequences (2a)-(2b)-(2c) started at even tact intervals) may be moved into a second subset of the deposition modules including the second-line first deposition module D1′, the second-line second deposition module, and at least one further second-line deposition module, but not into the first subset of deposition modules.

In particular, the method according to some embodiments described herein which are carried out in a multi-line-system may include (2a) routing, one tact interval after stage (1a), a subsequent substrate out of the main transportation path 50 into the second-line first deposition module D1′ for depositing the first material on the subsequent substrate, and (2b) routing, one tact interval after stage (1b), the subsequent substrate out of the main transportation path 50 into the second-line second deposition module D2′ for depositing the second material on the subsequent substrate.

Further, the method may include, in stage (2c), routing the subsequent substrate out of the main transportation path 50 into one or more further second-line deposition modules for depositing the one or more further materials on the further substrate. The respective routing stages may be offset by one tact interval with respect the corresponding routings of the substrate 10 of the previous sequence (1a)-(1b)-(1c).

In other words, two coating lines may be provided for alternately coating subsequent substrates. The even sequences (1a)-(1b)-(1c) in which a substrate is coated in the first coating line may start for respective subsequent substrates after predetermined time intervals which may correspond to twice the tact interval of the system. The odd sequences (2a)-(2b)-(2c) in which a substrate is coated in the second coating line may start for respective subsequent substrates after predetermined time intervals which may correspond to twice the tact interval of the system. The two coating lines in combination may provide the overall tact time of the vacuum processing system, whereas each of the two coating lines may start a new coating sequence at every second tact interval. A two-line system may be larger and more costly than a single-line-system. However, a failure or a downtime of one of the coating lines does not lead to a downtime of the whole system.

It is to be noted that, similarly to the methods described above, in every second even sequence (1a)-(1b)-(1c), the respective substrate may be coated in the first deposition areas of the first subset of deposition modules, and in the other even sequences (1a)-(1b)-(1c), the respective substrate may be coated in the second deposition areas of the first subset of deposition modules. In some embodiments, in every second odd sequence (2a)-(2b)-(2c), the respective substrate may be coated in the first deposition areas of the second subset of deposition modules, and in the other odd sequences (2a)-(2b)-(2c), the respective substrate may be coated in the second deposition areas of the second subset of deposition modules. In other words, a substrate exchange in a given deposition area may be carried out in time intervals corresponding to four tact intervals.

The vacuum processing system 200 of FIG. 4 may be operated similarly to the vacuum processing system 100 of FIG. 1, so that reference can be made to the above explanations which are not repeated here.

In particular, the above mentioned sequence of stages (1a)-(1b)-(1c) may be carried out in the first line including the first deposition module D1 and the second deposition module D2, e.g. at a tact rate corresponding half the tact rate of the whole system.

A similar sequence of stages (2a)-(2b)-(2c) may be carried out in the second line including the second-line first deposition module D1′ and the second-rate deposition module D2′, e.g. at the same tact rate corresponding to half the tact rate of the whole system.

The sequences (1a)-(1b)-(1c) and (2a)-(2b)-(2c) may start alternately at the tact rate of the whole system.

Every sequence of stages (1a)-(1b)-(1c) may include a plurality of intermediate stages. For example, for routing a substrate into the first deposition module D1, the sequence of subsequent stages (1a-1)-(1a-2)-(1a-3)-(1a-4)-(1a)-(1a-5)-(1a-6)-(1a-7)-(1a-8) may be carried out. The first angle of stage (1a-2) may be, e.g., +60°, and the fourth angle of stage (1a-7) may be, e.g., −60°, in accordance with the orientation of the deposition modules with respect to the main transportation path. Alternatively, depending on the arrangement of the deposition modules around the respective rotation module, the first angle and/or the fourth angle may be +/−60° or +/−120° or any other angle, as may be appropriate for a respective substrate exchange.

It is to be noted that a rotation angle of a rotation module of +x° as used herein corresponds to a rotation angle of −(360°−x°) so that every negative angle can also be expressed as a positive angle. For example, a clockwise rotation of 60° corresponds to a counterclockwise rotation of 300°. The rotation directions of the rotation modules can be counterclockwise or clockwise in any of the rotation movements described herein.

After the deposition of the first material on the substrate 10 in the first deposition module D1, the substrate 10 may be moved back into the first rotation module R1, may be rotated in the first rotation module R1, particularly including two rotations by angles of 180°, and may be moved into the second deposition module D2 in stage (1b) to be coated with the second material.

In some embodiments, a subsequent sequence (2a)-(2b)-(2c) may start one tact interval subsequent to stage (1a) of a sequence (1a)-(1b)-(1c). The tact interval may be 45 seconds or more and 120 seconds or less, particularly about 60 seconds.

The subsequent sequence (2a)-(2b)-(2c) may include moving a subsequent substrate along the main transportation path 50 in the main transportation direction Z, particularly into the first rotation module R1. In stage (2a), the subsequent substrate may be routed out of the main transportation path 50 into the second-line first deposition module D1′ for depositing the first material on the subsequent substrate. In particular, in stage (2a), the subsequent substrate may be routed into a second deposition area of the second-line first deposition module D1′. Thereafter, in stage (2b), the subsequent substrate may be moved from the first rotation module R1 into the second-line second deposition module D2′ for depositing the second material on the subsequent substrate. In particular, in stage (2a), the subsequent substrate may be moved into a second deposition area of the second-line second deposition module D2′.

In some embodiments, a second subsequent sequence (1a)-(1b)-(1c) for a second subsequent substrate may start one tact interval subsequent to stage (2a) of the subsequent sequence.

The second subsequent sequence (1a)-(1b)-(1c) may include moving a second subsequent substrate along the main transportation path 50 in the main transportation direction Z, particularly into the first rotation module R1. In stage (1a), the second subsequent substrate may be routed out of the main transportation path 50 into the first deposition module D1 for depositing the first material on the second subsequent substrate. In particular, in stage (1a), the second subsequent substrate may be routed into a second deposition area of the first deposition module D1. Thereafter, in stage (1b), the second subsequent substrate may be moved from the first rotation module R1 into the second deposition module D2 for depositing the second material on the second subsequent substrate. In particular, in stage (1b), the second subsequent substrate may be routed into the second deposition area of the second deposition module D2.

In some embodiments, a third subsequent sequence (2a)-(2b)-(2c) may start one tact interval subsequent to stage (1a) of the second subsequent sequence (1a)-(1b)-(1c).

The third subsequent sequence may include moving a third subsequent substrate along the main transportation path 50 in the main transportation direction Z, particularly into the first rotation module R1. In stage (2a), the third subsequent substrate may be routed out of the main transportation path 50 from the first rotation module R1 into the second-line first deposition module D1′ for depositing the first material on the third subsequent substrate. In particular, in stage (2a), the third subsequent substrate may be routed into a first deposition area of the second-line first deposition module Dr. Thereafter, in stage (2b), the third subsequent substrate may be moved from the first rotation module R1 into the second-line second deposition module D2′ for depositing the second material on the third subsequent substrate. In particular, in stage (2b), the third subsequent substrate may be moved from the first rotation module R1 into the first deposition area of the second-line second deposition module D2′.

In some embodiments, a fourth subsequent sequence (1a)-(1b)-(1c) may start one tact interval after the start of the third subsequence sequence, wherein the movement path of the fourth subsequent substrate of the fourth subsequence sequence may correspond to the movement path of the first substrate of the first sequence. In particular, stage (1a) of the fourth subsequent sequence may be carried out at approximately the same time as stage (1b) of the first sequence. In other words, when the fourth subsequent substrate is routed into the first deposition module D1, the coating of the first substrate in the first deposition module has finished, and the first substrate is on the way from the first deposition module D1 into the second deposition module D2. Accordingly, when the cycle tact is about 60 seconds, the movement sequence of the rotation modules may be repeated about every 240 seconds.

The vacuum processing system 200 of FIG. 4 may be operated at a tact interval corresponding to the tact interval of the vacuum processing system 100 of FIG. 1, e.g. at a tact interval of about 60 seconds. One coated substrate may be provided after every tact interval corresponding to the tact time of the system. Since the vacuum processing system 200 is a two-line-system, the vacuum processing system 200 may have twice the amount of deposition modules as compared to the single-line-system depicted in FIG. 1. Accordingly, the substrates may stay in the deposition areas for a longer time period as compared to the embodiment of FIG. 1. There may be more time for substrate alignment with respect to a respective mask device. In particular, there may be more time for depositing the respective material on the substrates in the deposition areas. For example, in multi-line-systems, the deposition sources may move at a slower velocity as compared to single-line-systems, e.g. at half the velocity, which may increase the deposition rate. Accordingly, the deposition flexibility may be increased and a broader range of layer thicknesses can be deposited in every deposition module in a multi-line-system.

Corresponding modules may be operated synchronously in a multi-line system. For example, the rotation modules of the two-line systems of FIG. 4 or FIG. 5 (e.g. the first rotation module R1 and the second rotation module R2) may be operated synchronously for rotating respective substrates which may be timely delayed by a multiple of the tact interval of the system.

Alternatively or additionally, subsets of deposition modules may be operated synchronously. For example, the first-line deposition modules may be operated essentially synchronously, and the second-line deposition modules may be operated essentially synchronously. The first-line deposition modules and the second-line deposition modules may operate with a time delay of approximately one tact interval.

In some embodiments, there may be a time delay between the first-line (second-line) deposition modules arranged on the first side S1 and the first-line (second-line) deposition modules arranged on the second side S2, due to the time duration of a substrate exchange between deposition modules arranged on opposite sides of the main transportation path.

In some embodiments, deposition modules arranged at corresponding angular position adjacent to a respective rotation module may be operated synchronously (e.g. a respective deposition source may be at the same coating position within the respective deposition modules). For example, the second deposition module D2 and the third deposition module D3 in FIG. 4 may be operated synchronously, and the second-line second deposition module D2′ and the second-line third deposition module D3′ in FIG. 4 may be operated synchronously. Similarly, all the first-line deposition modules of the vacuum processing system 300 of FIG. 5 may be operated synchronously, and all the second-line deposition modules of the vacuum processing system 300 of FIG. 5 may be operated synchronously.

In some embodiments, which may be combined with other embodiments described herein, the vacuum processing system may further include a mask handling module 60, also referred to as a mask handling chamber. In some embodiments, the mask handling module 60 is arranged in the main transportation path 50. Used mask devices may be transported into the mask handling module 60 to be unloaded from the vacuum processing system, e.g. via a load lock chamber. Mask devices to be used may be loaded from an environment of the vacuum processing system into the mask handling module 60 to be transported into one of the deposition chambers.

For example, in some embodiments, a first mask carrier track may be provided for the transport of mask carriers holding mask devices to be used from the mask handling module 60 into the deposition modules, and a second mask carrier track may be provided for the transport of mask carriers holding used mask devices from the deposition modules into the mask handling area to be unloaded from the system. For example, one or more mask handling assemblies, e.g. robot devices, may be provided in the mask handling module for attaching and/or detaching mask devices from mask carriers.

The transport of the mask devices may be at least partially synchronized with the transport of the substrates in the vacuum processing system. Reference is made to the above explanations, which are not repeated here.

The vacuum processing system 200 of FIG. 4 may be operated according to one or more of the following parameters: The time for rotating a rotation module between two rotation positions may be 3 seconds or more and 10 seconds or less, particularly about 5 seconds; the time for moving a carrier from a vacuum module to an adjacent vacuum module may be 3 seconds or more and 10 seconds or less, particularly about 5 seconds; all rotation modules of the system may be synchronized; a forward and a backward transport of substrates along the main transportation path may be possible at the same time; the time interval between subsequent substrate exchanges involving only the first-line deposition modules may be about 120 seconds (90 seconds or more and 150 seconds or less); the time interval between subsequent substrate exchanges involving only the second-line deposition modules may be about 120 seconds (90 seconds or more and 150 seconds or less); the overall tact interval of the system may be about 60 seconds (45 seconds or more and 75 seconds or less).

FIG. 5 shows a vacuum processing system 300 according to some embodiments described herein in a schematic view. The vacuum processing system 300 can be used to carry out any of the methods described herein, so that reference can be made to the above explanations which are not repeated here.

The vacuum processing system 300 may be configured as a mirror line which has an essentially symmetric configuration with respect to the main transportation path 50. For example, deposition modules for depositing the first material may be arranged symmetrically with respect to each other on opposite sides of the main transportation path, and deposition modules for depositing the second material may be arranged symmetrically with respect to each other on opposite sides of the main transportation path.

The methods according to embodiments described herein may be carried out in the vacuum processing system 300 depicted in FIG. 5. The vacuum processing system 300 may include one or more transit modules, e.g. a first transit module T1, a second transit module T2 and a third transit module T3, a first rotation module R1 and a second rotation module R2 provided along the main transportation path 50. Further transit modules and/or further rotation modules may be provided along the main transportation path 50.

In some embodiments, a two-line-system may be provided. A first subset of deposition modules—also referred to herein as first-line deposition modules—may be arranged on the first side S1 of the main transportation path and provide a first line for depositing a predetermined layer stack on a plurality of substrates. For example, the first deposition module D1 for depositing the first material may be arranged adjacent to the first rotation module R1 on the first side S1 of the main transportation path 50, and a second deposition module D2 for depositing the second material may be arranged adjacent to the second rotation module R2 on the first side S1 of the main transportation path 50.

A second subset of deposition modules—also referred to herein as second-line deposition modules—may be arranged on the second side S2 of the main transportation path and provide a second line for depositing the predetermined layer stack on a plurality of substrates. For example, a second-line first deposition module D1′ for depositing the first material may be arranged adjacent to the first rotation module R1 on a second side S2 of the main transportation path 50 opposite the first side S1, particularly symmetrically to the first deposition module D1. Further, a second-line second deposition module D2′ for depositing the second material may be arranged adjacent to the second rotation module R2 on the second side S2 of the main transportation path 50, particularly symmetrically to the second deposition module.

In particular, the vacuum processing system 300 may be configured as a mirror line. The deposition modules arranged on the first side S1 of the main transportation path 50 may be used for the deposition of a plurality of materials on substrates. Similarly, the deposition modules arranged on the second side S2 of the main transportation path 50 may be used for the deposition of the plurality of materials on substrates. Accordingly, in the case of an interruption or a defect in one deposition module arranged on one side of the main transportation path, the deposition modules arranged on the other side of the main transportation path may continue with the deposition, so that the vacuum processing system can continue to work with a decreased substrate output rate.

The vacuum processing system 300 may be operated in accordance with the previously described methods so that reference can be made to the above embodiments, which are not repeated here.

For example, corresponding modules may be operated synchronously. In particular, the rotation modules of the two-line system of FIG. 5 (e.g., the first rotation module R1 and the second rotation module R2) may be operated synchronously for rotating respective substrates which may be timely delayed by a multiple of one tact interval of the system.

In some embodiments, the first-line deposition modules may be operated synchronously, and/or the second-line deposition modules may be operated synchronously. There may be a time delay of about one tact interval between the first-line deposition modules and the second-line deposition modules (e.g., corresponding positions of the respective deposition sources may be adopted at a temporal delay of one tact interval).

In some embodiments, the carrier transport along the first substrate carrier track 31 may be synchronous, as is schematically illustrated by respective arrows in FIG. 5. The transport of empty carriers 21 in the return direction along the second substrate carrier track 32 may be synchronous, as is schematically illustrated by respective arrows in FIG. 5.

In the following, an exemplary method of operating the vacuum processing system 300 will be described.

A substrate 10 may be moved along the main transportation path 50 onto a first track X1 of the first rotation module R1.

Thereafter, the first rotation module R1 may be rotated by a first angle, particularly by an angle of about +90° or −90°. The first angle may be an arbitrary angle which may depend on the orientation of the first deposition module D1 with respect to the main transportation path. For example, in the embodiment depicted in FIG. 5, the first angle may be an angle of −90°. In other words, the first rotation module R1 may be rotated from the first rotation position that is depicted in FIG. 5 to the second rotation position.

Thereafter, in stage (1a), the substrate 10 may be moved into a first deposition area of the first deposition module D1 from the first track X1 of the first rotation module R1. In the first deposition area of the first deposition module D1, the first material is deposited on the substrate 10.

In some embodiments, which may be combined with other embodiments described herein, a previous substrate 16 may be moved out of the first deposition area back into the main transportation path 50, before the substrate 10 is moved onto the first track X1 of the first rotation module R1. In particular, the previous substrate 16 may be moved out of the first deposition area into the rotation module R1, whereupon the first rotation module R1 may be rotated by a second angle, whereupon the previous substrate 16 may be moved out of the first rotation module R1 along the main transportation path 50 toward the second rotation module R2 to be routed into the second deposition module D2.

In some embodiments, the second angle may be +90°. However, the second angle may depend on the orientation of the respective deposition module with respect to the main transportation path. For example, the second angle may be −90° or another angle. In particular, the first rotation module may be rotated back to the first rotation position that is depicted in FIG. 5.

After the routing of the previous substrate back into the main transportation path, the substrate 10 may be moved onto the first track X1 of the first rotation module R1 in stage to be routed into the first deposition module D1 in stage (1a).

After the deposition of the first material on the substrate 10, the substrate 10 may be routed back into the main transportation path, may be moved along the main transportation path 50 into the second rotation module R2, may be rotated in the second rotation module, particularly by an angle of −90°, and may be moved into the second deposition module D2 from the second rotation module R2 in stage (1b). The second material may be deposited on the substrate in the second deposition module D2.

In stage (1c), the substrate 10 may be routed into further deposition modules arranged on the first side S1 to be coated with further materials.

In some embodiments, a subsequent sequence (2a)-(2b)-(2c) may start at a predetermined time interval, particularly one tact interval, subsequent to stage (1a) of the sequence (1a)-(1b)-(1c). The tact interval may be 45 seconds or more and 120 seconds or less, particularly about 60 seconds.

The subsequent sequence (2a)-(2b)-(2c) may include moving a subsequent substrate along the main transportation path 50 in the main transportation direction Z, particularly into the first rotation module R1. In stage (2a), the subsequent substrate may be routed out of the main transportation path 50 into the second-line first deposition module D1′ for depositing the first material on the subsequent substrate. In particular, in stage (2a), the subsequent substrate may be routed into a second deposition area of the second-line first deposition module D1′. Thereafter, in stage (2b), the subsequent substrate may be routed out of the main transportation path 50 into the second-line second deposition module D2′ for depositing the second material on the subsequent substrate. In particular, in stage (2b), the subsequent substrate may be routed into a second deposition area of the second-line second deposition module D2′.

In some embodiments, a second subsequent sequence (1a)-(1b)-(1c) may start one tact interval subsequent to stage (2a) of the subsequent sequence.

The second subsequent sequence may include moving a second subsequent substrate along the main transportation path 50 in the main transportation direction Z, particularly into the first rotation module R1. In stage (1a), the second subsequent substrate may be routed out of the main transportation path 50 into the first deposition module D1 for depositing the first material on the second subsequent substrate. In particular, in stage (1a), the second subsequent substrate may be routed into a second deposition area of the first deposition module D1. Thereafter, in stage (1b), the second subsequent substrate may be routed out of the main transportation path 50 into the second deposition module D2 for depositing the second material on the second subsequent substrate. In particular, in stage (2b), the second subsequent substrate may be routed into the second deposition area of the second deposition module D2.

In some embodiments, a third subsequent sequence (2a)-(2b)-(2c) may start one tact interval subsequent to stage (1a) of the second subsequent sequence.

The third subsequent sequence may include moving a third subsequent substrate along the main transportation path 50 in the main transportation direction Z, particularly into the first rotation module R1. In stage (2a), the third subsequent substrate may be routed out of the main transportation path 50 into the second-line first deposition module D1′ for depositing the first material on the third subsequent substrate. In particular, in stage (2a), the third subsequent substrate may be routed into a first deposition area of the second-line first deposition module D1′. Thereafter, in stage (2b), the third subsequent substrate may be routed out of the main transportation path 50 into the second-line second deposition module D2′ for depositing the second material on the third subsequent substrate. In particular, in stage (2b), the third subsequent substrate may be routed into the first deposition area of the second-line second deposition module D2′.

In some embodiments, a fourth subsequent sequence may start one tact interval afterwards, wherein the movement path of the fourth subsequent substrate of the fourth subsequent sequence may correspond to the movement of the substrate of the first sequence. Stage (1a) of the fourth subsequent sequence may be carried out at approximately the same time as stage (1b) of the first sequence. In other words, when the fourth subsequent substrate is routed into the first deposition module D1, the first substrate may be moved from the first deposition module D1 toward the second deposition module D2. Accordingly, when the tact interval is about 60 seconds, a corresponding movement sequence may repeat about every 240 seconds.

The vacuum processing system 300 of FIG. 5 may be operated at a tact interval corresponding to the tact interval of the vacuum processing system 100 of FIG. 1, e.g. at a tact interval of about 60 seconds. One coated substrate may be provided after every tact interval corresponding to the tact time of the system. Since the vacuum processing system 300 is a two-line-system, the vacuum processing system 300 may have twice the amount of deposition modules as compared to the single-line-system depicted in FIG. 1. Accordingly, the substrates may stay in the deposition areas for a longer time period as compared to the embodiment of FIG. 1. There may be more time for substrate alignment with respect to a respective mask device. In particular, there may be more time for depositing the respective material on the substrates in the deposition areas. For example, in a two-line-system, the deposition sources may move at a slower speed as compared to a single-line-system, e.g. at half the speed, which may increase the deposition rate. Accordingly, the deposition flexibility may be increased and a broader range of layer thicknesses can be deposited in every deposition module.

The vacuum processing system 300 of FIG. 5 may be operated according to one or more of the following parameters: the time for rotating a rotation module between two rotation positions may be 3 seconds or more and 10 seconds or less, particularly about 5 seconds; the time for moving a carrier from a vacuum module to an adjacent vacuum module may be 3 seconds or more and 10 seconds or less, particularly about 5 seconds; all rotation modules of the system may be synchronized; a forward and a backward transport of substrates along the main transportation path may be possible at the same time; the time interval between subsequent substrate exchanges involving only the first-line deposition modules may be about 120 seconds (90 seconds or more and 150 seconds or less); the time interval between subsequent substrate exchanges involving only the second-line deposition modules may be 120 seconds (90 seconds or more and 150 seconds or less); the overall tact interval of the system may be about 60 seconds (45 seconds or more and 75 seconds or less).

In the following paragraphs, various methods of operating a vacuum processing system with at least one rotation module according to embodiments are described. The vacuum processing system may be a vacuum processing system according to any of the embodiments described herein. Said methods are meant to accelerate the mask traffic and/or the substrate traffic in the vacuum processing system in order to reduce the tact time of the vacuum processing system.

In particular, the vacuum processing system may have two or more rotation modules arranged along a main transportation path, wherein one of the following operation methods is carried out synchronously in each of the rotation modules.

According to one aspect, a method of operating a vacuum processing system with a rotation module is described. The method includes moving, during a time period, a first carrier carrying a substrate or a mask device on a first track in a first direction into the rotation module (or out of the rotation module), and moving, during the same time period (i.e. synchronously), a second carrier on a second track in a second direction opposite to the first direction into the rotation module or out of the rotation module. Accordingly, one rotation module may be used for synchronous mask and/or substrate transport in opposite directions through the rotation module. For example, a substrate may be moved into the rotation module in a first direction, and a mask device, a second substrate and/or an empty carrier may be moved into or out of the rotation module on another track in an opposite direction. For example, a substrate 10 may be moved on a first carrier into the rotation module in a first direction on a first substrate carrier track 31, and an empty carrier 21 may synchronously be moved out of the rotation module on a second substrate carrier track 32 in an opposite direction, as is schematically depicted in FIG. 1.

According to one aspect, a method of operating a vacuum processing system with a rotation module is described. The method includes moving, during a time period, a first carrier carrying a first substrate on a first track in a first direction out of the rotation module, and moving, during the same time period (i.e. synchronously), a second carrier carrying a second substrate on the first track in the first direction into the rotation module. Substrate exchange in two deposition modules arranged on opposite sides of the rotation module may be accelerated and idle times of the rotation module can be reduced. For example, in stage (1a) of the operation methods described herein, a first substrate may be moved from a first track of a rotation module in a first direction into a deposition module, while a second substrate may be synchronously moved onto the first track of the rotation module in the first direction from an oppositely arranged deposition module.

According to one aspect, a method of operating a vacuum processing system with a rotation module is described. The method includes moving a first carrier carrying a first substrate or a first mask device on a first track into the rotation module, while a second carrier carrying a second substrate is arranged on a second track in the rotation module and/or while a third carrier carrying a second mask device is arranged on a third track in the rotation module. A substrate exchange in a deposition area arranged adjacent to the rotation module can be accelerated, because more than one track of the rotation module can be beneficially used for removal of the coated substrate and the insertion of the substrate to be coated from/into a deposition area. For example, in stage (1a) of the operation methods described herein, the first track and the second track of a rotation module may synchronously be occupied by substrate carriers.

According to one aspect, a method of operating a vacuum processing system with a rotation module is described. The method includes moving a first carrier carrying a substrate on a first track into the rotation module and moving a second carrier carrying a mask device on a second track adjacent to the first track into the rotation module, and simultaneously rotating the first carrier and the second carrier in the rotation module. In particular, one rotation module can at the same time be used for both substrate exchange and mask exchange in an adjacent deposition module.

According to one aspect, a method of operating a vacuum processing system with a rotation module is described. The method includes moving, during a first time period, a coated substrate and a used mask device from the deposition area into the rotation module, followed by synchronously rotating the coated substrate and the used mask device in the rotation module during a second time period.

Alternatively or additionally, the method may include moving, during a third time period, a substrate to be coated and a mask device to be used from a main transportation path into the rotation module, followed by synchronously rotating the substrate to be coated and the mask device to be used in the rotation module during a fourth time period. Mask exchange and substrate exchange can be synchronized and the tact interval of the vacuum processing system can be reduced.

While the foregoing is directed to embodiments of the disclosure, other and further embodiments of the disclosure may be devised without departing from the basic scope thereof, and the scope thereof is determined by the claims that follow.

1. A method of operating a vacuum processing system with a main transportation path along which substrates can be transported in a main transportation direction, comprising:
(1a) routing a substrate out of the main transportation path into a first deposition module for depositing a first material on the substrate;
(1b) routing the substrate out of the main transportation path into a second deposition module for depositing a second material on the substrate; and
(1c) routing the substrate out of the main transportation path into one or more further deposition modules for depositing one or more further materials on the substrate.

2. The method of claim 1, wherein each routing (1a)-(1b)-(1c) repeatedly starts for subsequent substrates after predetermined time intervals, wherein the predetermined time intervals are constant time intervals corresponding to tact intervals of the vacuum processing system.

3. The method of claim 2, wherein, in stages (1a) of sequences started at odd tact intervals, a substrate is routed into a first deposition area of the first deposition module for depositing the first material on the substrate, and wherein, in stages (1a) of sequences started at even tact intervals, a substrate is routed into a second deposition area of the first deposition module for depositing the first material on the substrate.

4. The method of claim 1, comprising:
(2a) routing, one tact interval after stage (1a), a subsequent substrate out of the main transportation path into a second-line first deposition module for depositing the first material on the subsequent substrate; and
(2b) routing, one tact interval after stage (1b), the subsequent substrate out of the main transportation path into a second-line second deposition module for depositing the second material on the subsequent substrate.

5. The method of claim 4, wherein sequences (1a)-(1b) and sequences (2a)-(2b) alternately start for subsequent substrates after predetermined time intervals.

6. The method of claim 1, wherein, in stage (1a), the substrate is moved into the first deposition module from a first rotation module, and wherein, after depositing the first material, the substrate is moved back into the first rotation module.

7. The method of claim 6, wherein, in stage (1a), a third substrate is moved into the first rotation module from a second deposition module during a time period in which the substrate is moved out of the first rotation module.

8. The method of claim 6, wherein, in stage (1a), a second substrate is arranged on a second track of the first rotation module during a time period in which the substrate is moved out of the first rotation module from a first track of the first rotation module.

9. The method according to claim 1, comprising:
(1a-1) moving the substrate along the main transportation path onto a first track of a first rotation module;
(1a-2) rotating the first rotation module by a first angle;
(1a-3) moving a second substrate from the first deposition module onto a second track of the first rotation module;
(1a-4) rotating the first rotation module by a second angle; and
moving, in stage (1a), the substrate into the first deposition module from the first track of the first rotation module.

10. The method of claim 9, wherein, in stage (1a), a third substrate is moved onto the first track of the first rotation module from a second deposition module simultaneously with or subsequent to moving the substrate from the first track into the first deposition module.

11. The method of claim 9, further comprising:
(1a-5) rotating the first rotation module by a third angle;
(1a-6) moving the second substrate from the second track of the first rotation module into the second deposition module;
(1a-7) rotating the first rotation module by a fourth angle; and
(1a-8) moving the third substrate out of the first rotation module along the main transportation path.

12. The method of claim 1, wherein the vacuum processing system comprises at least one rotation module with two substrate carrier tracks for transporting substrate carriers and two mask carrier tracks for transporting mask carriers which can be rotated around a rotation axis.

13. The method of claim 1, wherein the main transportation path includes a first substrate carrier track and a second substrate carrier track arranged parallel to each other, wherein substrates are moved along the first substrate carrier track in the main transportation direction while being held by carriers.

14. The method of claim 1, wherein the vacuum processing system comprises:
one or more transit modules and a first rotation module provided along the main transportation path, wherein the first deposition module is arranged adjacent to the first rotation module on a first side of the main transportation path, and the second deposition module is arranged adjacent to the first rotation module on a second side of the main transportation path opposite the first deposition module.

15. The method claim 1, wherein the vacuum processing system comprises:
one or more transit modules and a first rotation module provided along the main transportation path, wherein the first deposition module is arranged adjacent to the first rotation module on a first side of the main transportation path, and the second deposition module is arranged adjacent to the first rotation module on a second side of the main transportation path opposite the first side, the vacuum processing system further comprising:
a second-line first deposition module for depositing the first material which is arranged adjacent to the first rotation module on the second side of the main transportation path; and
a second-line second deposition module for depositing the second material which is arranged adjacent to the first rotation module on the first side of the main transportation path.

16. The method of claim 1, wherein the vacuum processing system comprises:
one or more transit modules, a first rotation module and a second rotation module arranged along the main transportation path, wherein the first deposition module is arranged adjacent to the first rotation module on a first side of the main transportation path, and the second deposition module is arranged adjacent to the second rotation module on the first side of the main transportation path;
a second-line first deposition module for depositing the first material which is arranged adjacent to the first rotation module on a second side of the main transportation path opposite the first deposition module; and
a second-line second deposition module for depositing the second material which is arranged adjacent to the second rotation module on the second side of the main transportation path opposite the second deposition module.

17. The method of claim 1, wherein the vacuum processing system is configured as a mirror line which has an essentially symmetric configuration with respect to the main transportation path.

18. The method of claim 1, wherein one or more mask carrier tracks are provided which extend along the main transportation path, wherein:
a mask device to be used is transported along the main transportation path on one of the one or more mask carrier tracks; and
in stage (1a), the mask device to be used is routed out of the main transportation path into the first deposition module for masked deposition on the substrate.

19. The method of claim 18, wherein used mask devices are routed out of the first deposition module and mask devices to be used are routed into the first deposition module at a mask exchange frequency.

20. A method of operating a vacuum processing system with a rotation module, comprising:
moving, during a time period, a first carrier carrying a substrate or a mask device on a first track in a first direction into the rotation module; and
moving, during the time period, a second carrier on a second track in a second direction opposite to the first direction into the rotation module or out of the rotation module.

21. A method of operating a vacuum processing system with a rotation module, comprising:
moving, during a time period, a first carrier carrying a first substrate on a first track in a first direction out of the rotation module; and
moving, during the time period, a second carrier carrying a second substrate on the first track in the first direction into the rotation module.

22. A method of operating a vacuum processing system with a rotation module, comprising:
moving a first carrier carrying a first substrate or a first mask device on a first track into the rotation module, while a second carrier carrying a second substrate is arranged on a second track in the rotation module, and/or while a third carrier carrying a second mask device is arranged on a third track in the rotation module.

23. A method of operating a vacuum processing system with a rotation module, comprising:
moving a first carrier carrying a substrate on a first track into the rotation module and moving a second carrier carrying a mask device on a second track adjacent to the first track into the rotation module; and
simultaneously rotating the first carrier and the second carrier in the rotation module.

24. A method of operating a vacuum processing system with a rotation module and a deposition area, comprising:
moving, during a first time period, a coated substrate and a used mask device from the deposition area into the rotation module, followed by rotating the coated substrate and the used mask device in the rotation module during a second time period; and/or
moving, during a third time period, an substrate to be coated and a mask device to be used from a main transportation path into the rotation module, followed by rotating the substrate to be coated and the mask device to be used in the rotation module during a fourth time period.
